(19) United States
(12) Patent Application Publication
(10) Pub. No.: US 2026/0158951 A1
(43) Pub. Date: Jun. 11, 2026

(54) PAD FOR ELECTRIC VEHICLE SERVICE EQUIPMENT (EVSE)

(71) Applicant: EVgo Services LLC, Los Angeles, CA (US)

(72) Inventors: Ian STARNES, Los Angeles, CA (US); Gerald Steven MCALWEE, Dana Point, CA (US)

(21) Appl. No.: 19/415,280

(22) Filed: Dec. 10, 2025

Related U.S. Application Data
(60) Provisional application No. 63/730,361, filed on Dec. 10, 2024.

(51) Int. Cl. B60L 53/31; B60L 53/18; H05K 7/14; H05K 7/18

(52) U.S. Cl. CPC B60L 53/31; B60L 53/18; H05K 7/14325; H05K 7/18; B60L 2210/10; B60L 2210/30

(57) ABSTRACT

An electric vehicle service equipment (EVSE) assembly and/or mounting systems utilizing precast pads and/or slabs are described herein. For example, the EVSE assembly may include a prefabricated unitized composition (PUC) or precast pad, having two components, such as a top layer, or EVSE integration layer, and a bottom layer, or base ground interaction layer.

### CROSS-REFERENCE TO RELATED APPLICATIONS

This application claims priority to U.S. Provisional Ser. No. 63/730,361, filed on Dec. 10, 2024, entitled PRECAST PAD FOR ELECTRIC VEHICLE SERVICE EQUIPMENT (EVSE), which is hereby incorporated by reference in its entirety.

### BACKGROUND

Premanufactured foundations (e.g., “slabs”, “skids”, “foundations”, “footings”, and so on) for the mounting of electric vehicle service equipment (EVSE) are often constructed using bolted and/or welded metal frames, using different materials. For example, structures configured to mount EVSEs may include precast concrete with steel reinforcement, fiber reinforced composites (FRC), glass fiber reinforced concrete (GFRC), and/or other reinforced polymer resin systems (with a range of mineral and other aggregate compositions).

### BRIEF DESCRIPTION OF THE DRAWINGS

Embodiments of the present technology will be described and explained through the use of the accompanying drawings.

FIGS. 1-2A are diagrams illustrating an example EVSE assembly.

FIGS. 2B-2C are diagrams illustrating an example bottom layer for a precast pad of an EVSE assembly.

FIGS. 3-4 are diagrams illustrating another example EVSE assembly.

FIG. 5 is a diagram illustrating an example EVSE assembly with multiple connection troughs.

FIGS. 6A-6B are diagrams illustrating an example bottom layer having internal channels.

FIGS. 7A-7B are diagrams illustrating an example bottom layer with multiple connection troughs.

FIG. 8 is a diagram illustrating an example configuration of multiple EVSE assemblies.

FIG. 9 is a diagram illustrating an example bottom layer of a pad for an EVSE assembly.

FIGS. 10A-10F are diagrams illustrating example top layers of a pad for an EVSE assembly.

In the drawings, some components are not drawn to scale, and some components can be combined for some of the implementations of the present technology. Moreover, while the technology is amenable to various modifications and alternative forms, specific implementations have been shown by way of example in the drawings and are described in detail below. The intention, however, is not to limit the technology to the particular implementations described. On the contrary, the technology is intended to cover all modifications, equivalents, and alternatives falling within the scope of the technology as defined by the appended claims.

### DETAILED DESCRIPTION

### Overview

EVSE mounting systems utilizing precast pads, slabs, and/or multi-layer structures are described herein. While premanufactured foundations or structures are produced in factory/foundary molds, there are clear intrinsic benefits, including reduced build times, higher value features, scaling via separation of production schedules from the structures and an associated EVSE (e.g., an electric vehicle charging station). Such practices may allow increased deployment rates during favorable climactic construction periods, improved quality and uniformity for the product, reduced product transport cost with multi-location production, and the compounded effect of all these points in reducing both cost and resource constraints.

Such systems may suffer from various drawbacks, including issues associated with operations, maintenance, life cycle stability, compromised features, lower quality surface finishes, complexities in future proofing, and so on. For example, specific issues arise when utilizing single part or single material structures, including (1) integration of a slab with the EVSE (e.g., intra-slab wiring and pre-commissioning), (2) site preparations for coupling the EVSE to grid or micro-grid power sources and multi-source energy supply infrastructures with islanding ability, (3) use of adapter plates that force compromises to retain compliance with requirements for site installed height, (4) shipping weight, shipping quantities per truck, quantity, and so on, (5) water intrusion, (6) inability to install during inclement weather, (4) repair difficulty or unrepairable damage, (5) limited potential, low initial, and poor endurance of aesthetics to meet customer experience expectations, and so on.

A prefabricated unitized composition (PUC) or precast pad of an EVSE solution or solution set is described. The pad (or slab), in some examples, may include two components, such as a top layer, or EVSE integration layer, and a bottom layer, or base ground interaction layer. Thus, an EVSE assembly or apparatus may include a precast pad having a top layer disposed with a design interaction and a bottom layer, providing flexibility for mounting and/or supporting different types of chargers, components, or elements of the integrated top layer (e.g., a charging station and a power conversion cabinet) to complete the EVSE solution set or assembly.

For example, a precast pad for an EVSE assembly may include a top layer and a bottom layer, where a charger is mounted to the top layer of the precast pad and a power conversion cabinet is mounted to the top layer of the precast pad. Thus, the precast pad may simplify and/or enhance the installation of an EVSE assembly in a flexible, efficient, and/or cost-effective manner, among other benefits.

### Examples of a Precast Pad EVSE Assembly

As described herein, an EVSE assembly may be a multi-layer (e.g., two-layer) structure that includes a ground integration layer designed to be integrated into a site (e.g., disposed and placed at a ground site for a future EV charging station or area) and an EVSE integration layer designed to integrate EVSE components (e.g., chargers and/or power conversion cabinets) into the EVSE assembly.

The use of a multi-layer structure and/or system may facilitate the de-coupling of EVSE or power components (e.g., DC/AC integration) from support or foundation structures. For example, various power infrastructure components or objects may run through one or more layers of the multi-layer structure.

Further, the multi-layer structure may be prefabricated, flexible, and/or modular, where different layers may float or interlock, such as via physical form matching, fastened or fixed interfacing, and so on. The layers may be (fully) engineered elements or components that are constructed of various materials, including monolithic continuous phase materials (e.g., an organic resin or plastics/polymers), resin systems with inorganic or organic media compositions, dissimilar materials with oriented reinforcement (e.g., from rebar to small scale to glass fiber and/or carbon nanotube (CNT) reinforced concrete aggregates), and so on. Various layers may be formed of ferrous or non-ferrous, sintered metal multi-phase compression composites, laser sintered materials, and so on.

The integration of layers may be based on environmental or site conditions. For example, the layers may be integrated and/or configured to realize a composition level capacity to resist environmental, impact, and/or seismic site conditions. Thus, a top layer may be designed based on aesthetic, safety (anti-drill and anti-dig for NEC/municipal compliance) and/or ultraviolet (UV) resistance, and a bottom layer or under layer may be designed for strength to meet seismic and/or vehicle impact survival or to enable EVSE and infrastructure element attachment (e.g., via embedded or post build attachment features). For example, post build attachment features may be bonded or based on drilled anchor holes for pins, bolts, or cable solutions. Thus, EVSE or other infrastructure equipment may be fastened to any layer and/or attached to a multi-layered element (which may be secured to a unique layer of an adjacent multi-layer structure).

Further, layers may be formed as a solid structure to a skeletonized structure, with uni-facial, bi-facial, or multi-facial featuring. Layers may include internal empty cavities to achieve weight and/or mass-center specifications or objectives.

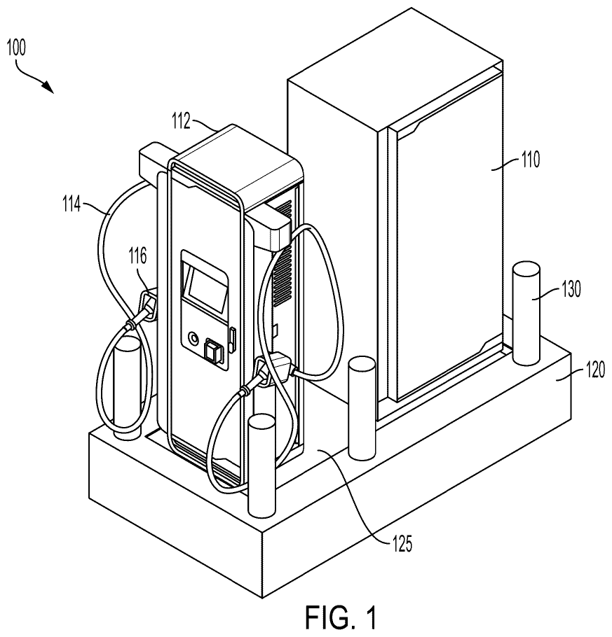

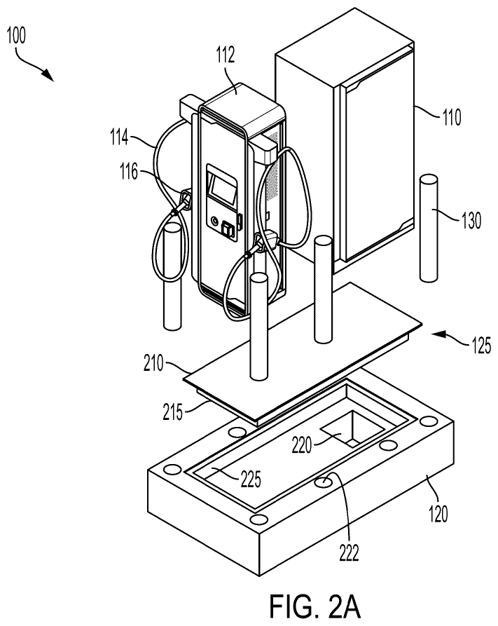

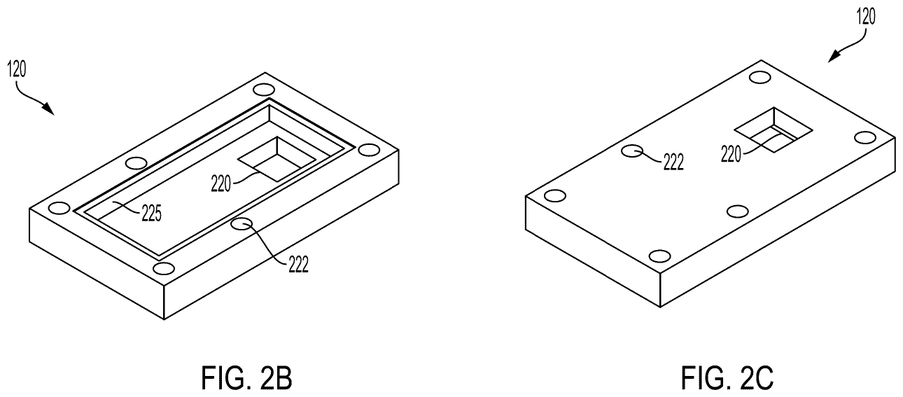

FIGS. 1-2A depict an example EVSE assembly 100. The EVSE assembly 100 may be formed of a precast pad, or PUC, such as a multi-layer or component structure. For example, the EVSE assembly 100 includes a bottom layer 120 and a top layer 125 disposed onto or within a top surface of the bottom layer 120.

The top layer 125 may support, mount, couple, or otherwise integrate EVSE components, such as a power conversion cabinet 110 (e.g., a power cabinet) and a charger 112, which may include a charging cable 114 and dispenser 116 that is used by EVs when charging at the EVSE assembly 100. In some cases, the top layer 125 may include two or more modular components, such as a mounting plate 210 disposed onto a base frame 215. The mounting plate 210 and/or the base frame 215 may be formed of metal, such as aluminum.

As depicted in FIGS. 2B-2C, the bottom layer 120 may include a top layer mounting area 225, such as an area within a top surface of the bottom layer 120 that has a geometry or shape that is designed or adapted to couple or mate to the base frame 215 of the top layer 125 (e.g., where the mounting 210 covers the top surface of the bottom layer 120 and the base plate 215 partially sits within the bottom layer 120).

The bottom layer 120 may also include one or more ducts 220 that are disposed on a top surface of the bottom layer 120 and extend into an internal area of the bottom layer 120. The ducts 220 may be conduit entrance points or interfaces, where conduit, cables, wires, or other components of the EVSE components may extend into the bottom layer 120 via the ducts 220. In some cases, the ducts 220 are positioned under or proximate to the EVSE components when the top layer 125 is mounted to the bottom layer 120. In some cases, the bottom layer also includes bollard sleeves 222 that are configured or formed to receive bollards 130, which function to protect the EVSE components from being impacted or otherwise harmed during use or operation. The bottom layer 120 may be formed of a polymer concrete or other similar material.

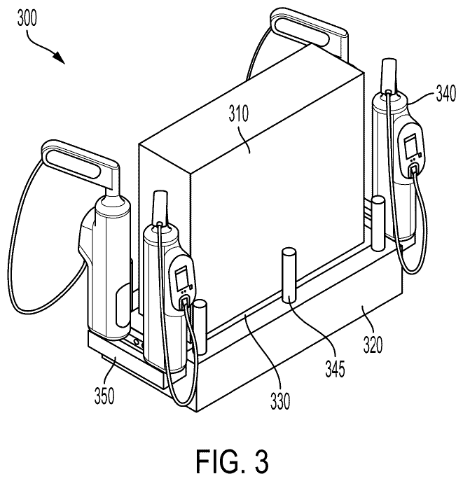

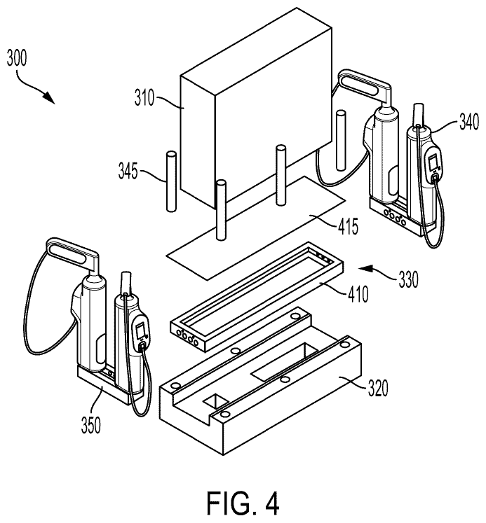

As described herein, in some examples, an EVSE assembly may include a top layer configuration that includes different frame components specifically designed to support different EVSE components. FIGS. 3-4 depict an EVSE assembly 300 that integrates EVSE components.

The EVSE assembly 300 includes a top layer 330 disposed onto a bottom layer 320, as described herein. The bottom layer 320 may be similar to other bottom layers described herein. For example, the bottom layer 320 includes ducts and supports bollards 345 (via bollard sleeves).

The top layer 330 supports EVSE components, such as a power conversion cabinet 310 and multiple chargers 340. The top layer 330 may be formed of multiple modular or integrated components, such as a base frame 410, one or more side frame components 315 disposed on each side (e.g., each end) of the base frame 410, and a metal plate 415 or cover disposed on top of the base frame 410 and the side frame components 315.

Further, in some cases, the base frame 410 may include one or more wireways that extend between the two side frame components 315 within the base frame and contain cables or wires (not shown) that extend between the power conversion cabinet 310 and the chargers 340 at each end of the EVSE assembly 300.

As shown, the base frame 410 supports the power conversion cabinet 310 and the side frame components 315 support the charger 340. While FIG. 4 shows two chargers 340, the EVSE assembly may utilize the base plate 410 and side frame components 315 to support or mount a single charger 340 (e.g., via one side frame component 315) or more than two chargers 340.

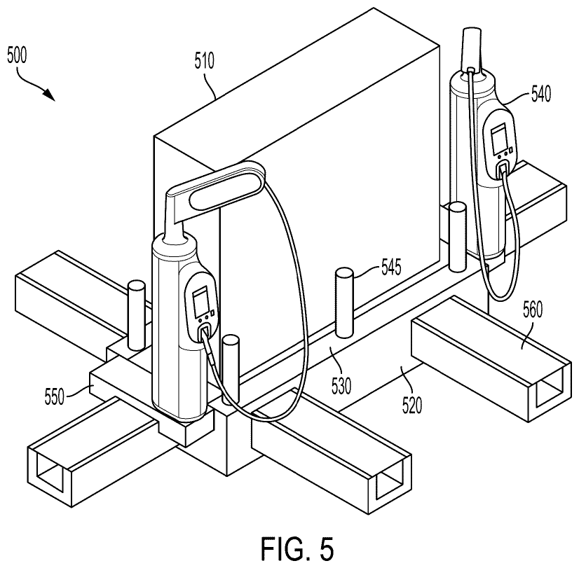

As described herein, in some examples, an EVSE assembly may have an internal area that facilitates the integration of the EVSE components (e.g., the power conversion cabinet 110 and/or chargers) with one another and/or the connection of one EVSE assembly to other EVSE assemblies at an area, site, or location. FIG. 5 is a diagram illustrating an example EVSE assembly 500 with multiple connection troughs.

The EVSE assembly 500, similar to the EVSE assembly 300, may include a top layer 530 disposed onto a bottom layer 520, as described herein. The top layer 430 supports EVSE components, such as a power conversion cabinet 510 and multiple chargers 540. The top layer 530 may be formed of multiple modular or integrated components (e.g., a base frame and/or mounting plate), including one or more side frame components 550 disposed on each side (e.g., each end) of the top layer 530.

In some cases, the EVSE assembly 500 includes one or more connection troughs 560 disposed proximate to the bottom layer 520 and configured to couple the EVSE assembly to other EVSE assemblies or other EVSE structures (e.g., a stand-alone power cabinet).

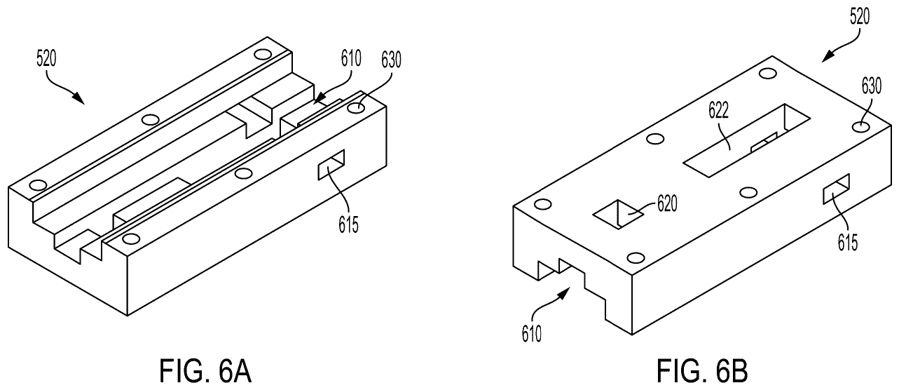

FIGS. 6A-6B depict the bottom layer 520, which may include various vertical and/or transverse levels that contain cables, conduit, wires, conductors, wireways, or other electrical components that extend within or through the bottom layer 520 to various external areas of the bottom layer 520 and/or the EVSE assembly 500. As described herein, the bottom layer 520 may be a pre-formed or precast structure of ducts, channels, troughs, via, or other internal passageways, interfaces, or areas that are adapted or configured to contain the electrical components.

For example, the bottom layer 520 (e.g., precast base layer) may include or integrate a channel 610 (or channels) that is configured to couple cable troughs 215 and contain cables (not shown) running through the bottom layer 520, such as cables that extend through the bottom layer 520 via the channel 610 or troughs 615 and/or out of the bottom layer 520 via the troughs 615. The troughs (e.g., cable troughs) 615 may be configured to to provide an exit point for the cables running within the bottom layer 520.

The bottom layer 520 also includes ducts 620, 622 disposed on a top surface of the bottom layer 520 and configured to receive a conduit (not shown) from the charger (e.g., the duct 620) and a conduit from the power conversion cabinet (e.g., the duct 622). The bottom layer 520 may also include bollard sleeves 630, as described herein.

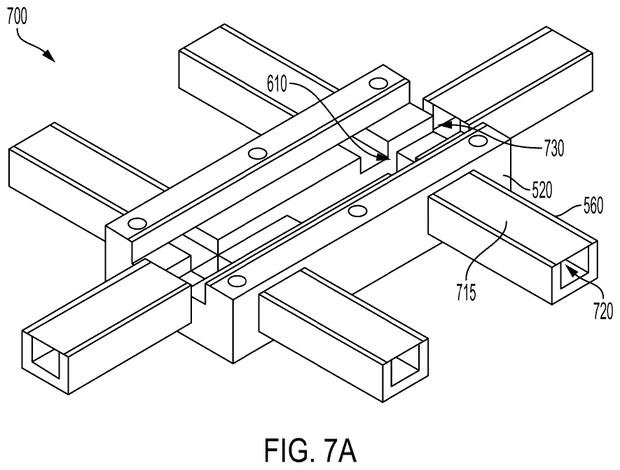

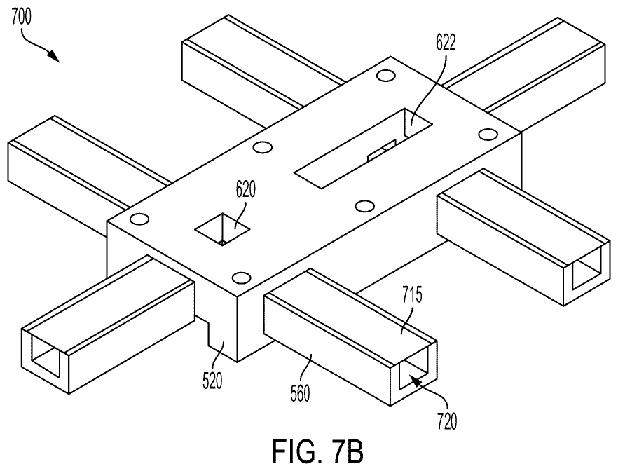

FIGS. 7A-7B are diagrams illustrating an example bottom layer 700 with multiple connection troughs, such as the connection troughs 560. For example, the connection troughs 560 may be disposed or positioned proximate to cable troughs (e.g., the cable trough 615) of the bottom layer 520 and configured to contain cables (not shown) running within an internal area 720 (via a cover 715) to a bottom layer of another EVSE assembly positioned adjacent to the EVSE assembly 500. The connection troughs 560 may be coupled to the channel 610 of the bottom layer 520 via one or more coupling interfaces 730 and/or the cable troughs 615 (e.g., at an exit interface of the cable through 615 within a side wall or side of the bottom layer 520).

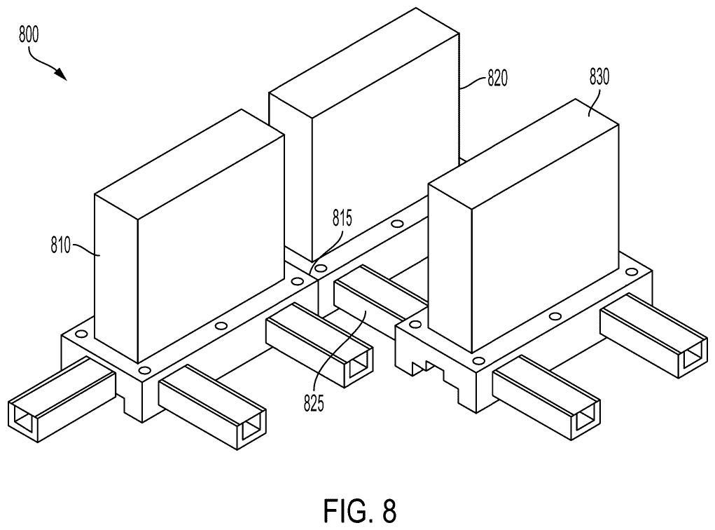

FIG. 8 illustrates an example configuration 800 of multiple EVSE assemblies. For example, a first EVSE assembly 810 is coupled directly to a second EVSE assembly 820 via a layer interface 815 at the bottom layers of the EVSE assemblies (e.g., via cable troughs or channels of the EVSE assemblies). A third EVSE assembly 830 may be coupled to the EVSE assembly 820 via a connection trough 825, as described herein. Thus, a configuration of EVSE assemblies may include various different numbers of EVSE assemblies connected or couples directly (e.g., via their base or bottom layers) and/or connected or coupled via a connection trough.

Further, the different EVSE assemblies may support similar or different EVSE components, and have different shapes, geometries, footprints, or layouts. Thus, a first configuration may be similar to the configuration 800, a second configuration may include two assemblies mounting four chargers and one assembly mounting a power cabinet, a third configuration may include a square shape of four unique EVSE assemblies, and so on.

Thus, the EVSE assemblies described herein may be two-layer or multi-layer structures that enable a simple and flexible manufacturing and/or installation of EVSE assemblies or equipment at a site.

For example, to manufacture or otherwise place an EVSE assembly at a site, the following steps may be performed: (1) excavate a site or area for precast pads and conduit entry to PC, (2) compact the soil, subbase, with or without designed additional loose or connected footing structures, (3) level the area with added gravel base, (4) lift the bottom layer and set in-place at the desired location, (5) dispose the integrated top layer onto the bottom layer, and (6) backfill the area. Thus, use of the precast pad structures describe herein may facilitate an efficient and simple initial installation of a charging station with an equally simple top layer exchange to allow scalable service replacement, site utilization adjustment, and future proofing - eliminating complex operations that to date have been restricted to inefficient and inconsistent on-site operations, among other benefits.

Thus, an EVSE assembly may be manufactured by disposing a base ground interaction layer (e.g., a bottom layer or base layer) onto a site and mounting an EVSE integration layer (e.g., a top layer) to the base ground interaction layer. Cables or other connectors or conductors may be coupled to one or more chargers and/or a power conversion cabinet of the EVSE integration layer by extending through conduit entrance ducts disposed on a top surface of the base ground interaction layer and within internal channels of the base ground interaction layer.

The layers, in some cases, may have compositional gradient, where each independent compositional gradient may be a bonded or un-bonded layer (with respect to the other compositional gradients). Further, layers may be applied to other layers in a variety of ways or manufacturing processes, including spray coating, heat and pressure lamination, dipping, adhesives, thermal sprays, sputtering, solution managed oxidation including anodizing, UV exposure to trigger cross-linking, and so on.

Thus, use of the multi-layer structures may enable the optimization of material property specifications for each layer of an EVSE assembly, facilitating improvements in cost, weight, manufacturing efficiency, and other benefits. For example, separate manufacturing and integration streams in a supply chain may produce components, leading to improved deployment scaling through logistics efficiency and/or reductions of construction time. Also, future changes to EVSE assemblies may be simplified and efficient, since changes made to EVSE or power equipment (e.g., top layer features or components) may be made without disruption to base/bottom ground layers (e.g., and thus not require permits, costly ground or site changes).

As described herein, the use of a precast pad can facilitate the flexible and/or modular assembly of EVSE equipment. A bottom layer of a precast pad may be disposed within (e.g., partially within) a top layer acting as a base or base layer for the precast pad. For example, the top layer may include an internal area having a geometry or configuration that matches a shape of the bottom layer.

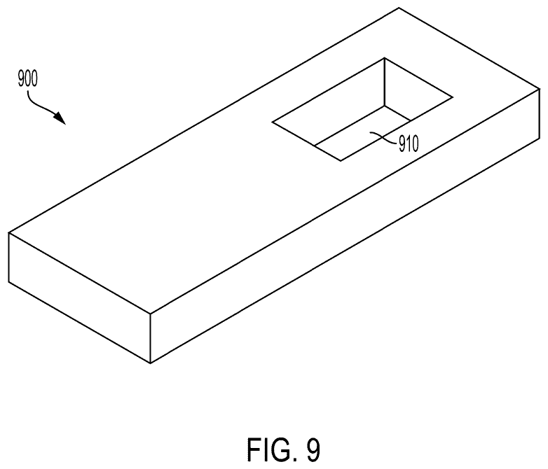

FIG. 9 is a diagram illustrating an example bottom layer 900 of a precast pad for an EVSE assembly (such as the EVSE assemblies described herein). The bottom layer 900 includes a conduit duct 910, entry drain, or opening, which may be positioned under a power cabinet of the EVSE assembly. As an example, the bottom layer 900 may have dimensions of ˜8.5 feet by ˜3.5 feet by ˜10 inches, have a mass of ˜2,395 lbs., and be formed of concrete (e.g., having a volume 16 ft³).

In some cases, the bottom layer 900 (or other bottom layers described herein) may be common to different top layers, with standard variations to meet different site condition requirements, all operating as in-ground foundations with a duct-like entrance for infrastructure power connections. The expanded design space using polymer and the range of hybrid reinforces compositions allows property optimization for each layer in a multi-layer composition (“PUC”) design that enable solutions with total slab weight (including EVSE and wire connection infrastructure) to have roughly half the weight of a single part and single material slab (including EVSE). Additionally, with the ability to manage the mass ratios between the top, bottom and other layers or ballasting inserts, the PUC system can have intrinsic system stability and be installed at a depth that meets topographic zone freeze-line requirements (e.g., determined to have the lowest installed cost relative to other methods, such as piers or other footing structures).

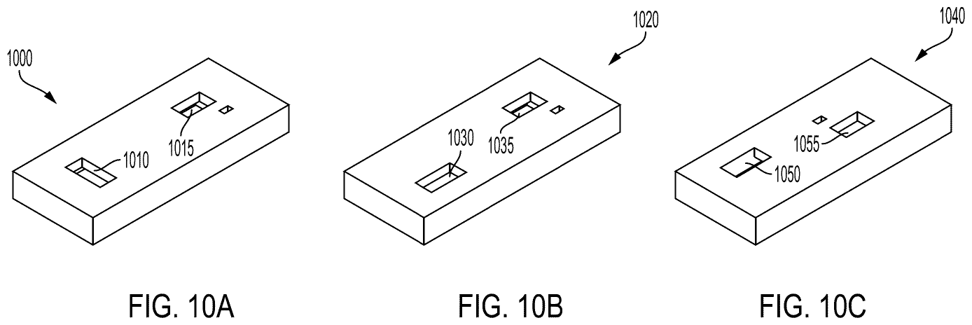

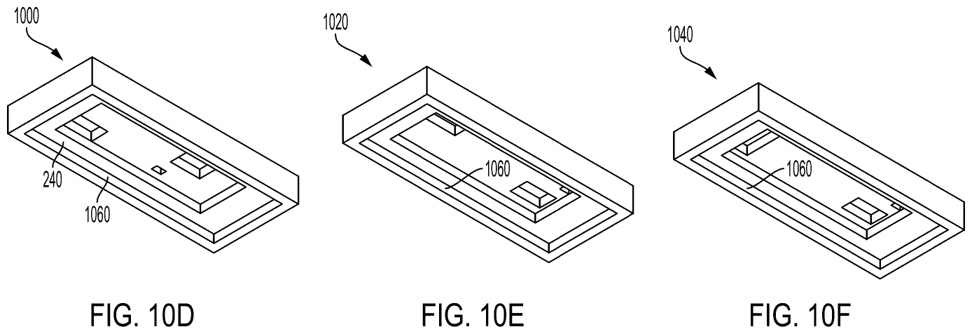

FIGS. 10A-10F are diagrams illustrating example top layers 1000, 1020, 1040 of a pad for an EVSE assembly. The top layers 1000, 1020, 1040 include charger interfaces 1010, 1030, 1050, such as island charger interfaces or head of stall charger interfaces, and power cabinet interfaces 1015, 1035, 1055. The charger interfaces may be configured to facilitate placement and/or mounting of a charger to a top layer and the power cabinet interfaces may be configured to facilitate placement and/or mounting of a power cabinet to a top layer.

The top layers may include a lip 1060 or edge, having a geometry or design that encloses a wireway within the precast pad and extends past and/or over the bottom layer. In some cases, the lip 1060 includes two portions or sections, a first portion to enclose a wireway and a second portion that fits over the bottom layer.

Thus, the top layers 1000, 1020, 1040 may include an inner area or geometry that facilitates the routing of cables and other wireway components within the precast pad and integrates with the bottom layer 900 to form a snug or water-tight placement at a site or area. As an example, the top layer may have dimensions of ˜8.5 feet by ˜3.5 feet by ˜1 foot, have a mass of ˜2,311 lbs., and be formed of concrete (e.g., having a volume 15.5 ft³). In some cases, the inner area may have a different geometry that matches the dimensions of the bottom layer 140 (e.g., the perimeter of a top surface of the bottom layer 140).

For the various EVSE assemblies described herein, the configuration and/or geometry of the different components may be adapted to contain or facilitate intra-slab wiring, meet safety coverage requirements (e.g., identified in NEC Table 300.5) for peak system operating voltages, provide dimensional tolerance and stability, and incorporate handling characteristics allowing for scalable pre-deployment integration of the EVSE assembly or multiple EVSE assemblies.

In some examples, the precast pads may incorporate other features, configurations, or components. For example, a precast pad may include a single primary part body with different arrangements of EVSE mounting plates and a central cover plate for paired EVSE set solutions.

As another example, a two component pad may include two different material compositions (e.g., fiber-reinforced resin type system) to optimize features, achieve overall design goals and reduce material costs. The precast pad may include a top layer having an underside continuous “footer” that would have a height to fit or contain conduit and/or a raceway containing intra-slab DC power wiring between an EVSE set - whether from a AC/DC Power Cabinet to an EVSE Dispenser/Pile or from a DC/DC Power Cabinet to an EVSE Dispenser/Pile. This wiring set can support one or more dedicated charging circuits for electric vehicles. The footer feature and self-registration between the top and bottom Layers may avoid bolting top and bottom layers together (e.g., simplifying both parts and reducing damage risks to threaded insert systems). Due to the top layer having both high tensile and compressive strength, its EVSE fastening locations can be thru-holes and use conventional concrete anchors.

Also, in some cases, when the bottom layer acts as a common base for all types of top layers, the bottom layer may include an infrastructure power duct entrance or structure, as described herein. A two-step top layer underside footer can register on the outside of the top layer and apply to the bottom layer compressive loads in reaction to any vehicle that impacts the assembly. Thus, the smaller base may be cost optimized within the parametric relationship between weight and depth for providing slab system stability and impact resistance (e.g., in areas of no extreme freeze-line depths).

### Examples of the EVSE Assemblies

As described herein, an EVSE assembly, may include a precast pad having: a top layer and a bottom layer, a charger mounted to the top layer of the precast pad, and a power conversion cabinet mounted to the top layer of the precast pad.

In some cases, the bottom layer is a precast base layer that includes one or more ducts disposed on a top surface of the precast base layer and configured to receive a conduit from the charger and a conduit from the power conversion cabinet, one or more cable troughs disposed within the precast base layer and configured to provide an exit point for cables running within the precast base layer, and one or more channels disposed within the precast base layer and configured to couple the one or more cable troughs and contain the cables running through the precast base layer.

In some cases, the precast base layer includes one or more integrated bollard sleeves.

In some cases, the EVSE assembly includes one or more connection troughs disposed proximate to at least one cable trough of the one or more cable troughs and configured to contain cables running from the precast base layer to a precast base layer of another EVSE assembly positioned adjacent to the EVSE assembly.

In some cases, the top layer comprises a precast metal frame upon which the charger and power conversion cabinet are mounted.

In some cases, the bottom layer includes a top surface having a geometry configured to receive the precast metal frame of the top layer.

In some cases, the precast metal frame includes a base frame, one or more side frame components disposed on a side of the base frame, and a metal plate disposed on top of the base frame and the one or more side frame components.

In some cases, the base frame supports the power conversion cabinet and the one or more side frame components support one or more chargers.

In some cases, the precast metal frame includes two side frame components disposed on each end of the base frame and configured to support a charger at each end of the EVSE assembly.

In some cases, the base frame includes one or more wireways that extend between the two side frame components within the base frame and contain cables or wires that extend between the power conversion cabinet and the chargers at each end of the EVSE assembly.

In some cases, the top layer is formed of aluminum and the bottom layer is formed of a concrete polymer.

In some cases, the top layer is partially disposed within the bottom layer.

In some cases, the bottom layer is partially disposed within the top layer.

In some examples, an apparatus (e.g., a base layer or bottom layer) for mounting an EVSE assembly includes one or more ducts disposed on a top surface and configured to couple the apparatus to one or more EVSE components, one or more cable troughs disposed within the apparatus and configured to provide an exit point for cables running within the apparatus, and one or more channels disposed within the apparatus and configured to couple the one or more cable troughs and contain the cables running through the apparatus.

In some cases, the apparatus includes a mounting area disposed within the top surface of the apparatus and configured to receive a mounting plate upon which the one or more EVSE components are mounted.

In some cases, the apparatus includes one or more bollard sleeves integrated into a perimeter area of the apparatus.

In some cases, the apparatus includes one or more connection troughs disposed proximate to at least one cable trough of the one or more cable troughs and configured to contain cables that extend out of the at least one cable trough to an external area of the apparatus.

In some examples, a method of manufacturing an EVSE assembly includes disposing a base ground interaction layer onto a site and mounting an EVSE integration layer to the base ground interaction layer.

In some cases, the EVSE integration layer includes one or more chargers and a power conversion cabinet coupled to a mounting plate. In some cases, the method includes connecting the one or more chargers to the power conversion cabinet via cables that extend through conduit entrance ducts disposed on a top surface of the base ground interaction layer and within internal channels of the base ground interaction layer.

### Conclusion

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof, means any connection or coupling, either direct or indirect, between two or more elements; the coupling of connection between the elements can be physical, logical, or a combination thereof. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or”, in reference to a list of two or more items, covers all of the following interpretations of the word: any of the items in the list, all of the items in the list, and any combination of the items in the list.

The above detailed description of embodiments of the disclosure is not intended to be exhaustive or to limit the teachings to the precise form disclosed above. While specific embodiments of, and examples for, the technology are described above for illustrative purposes, various equivalent modifications are possible within the scope of the disclosure, as those skilled in the relevant art will recognize.

The teachings of the disclosure provided herein can be applied to other systems, not necessarily the system described above. The elements and acts of the various embodiments described above can be combined to provide further embodiments.

Any patents and applications and other references noted above, including any that may be listed in accompanying filing papers, are incorporated herein by reference. Aspects of the disclosure can be modified, if necessary, to employ the systems, functions, and concepts of the various references described above to provide yet further embodiments of the disclosure.

These and other changes can be made to the disclosure in light of the above Detailed Description. While the above description describes certain embodiments of the disclosure, and describes the best mode contemplated, no matter how detailed the above appears in text, the teachings can be practiced in many ways. Details of the technology may vary considerably in its implementation details, while still being encompassed by the subject matter disclosed herein. As noted above, particular terminology used when describing certain features or aspects of the disclosure should not be taken to imply that the terminology is being redefined herein to be restricted to any specific characteristics, features, or aspects of the disclosure with which that terminology is associated. In general, the terms used in the following claims should not be construed to limit the disclosure to the specific embodiments disclosed in the specification, unless the above Detailed Description section explicitly defines such terms. Accordingly, the actual scope of the disclosure encompasses not only the disclosed embodiments, but also all equivalent ways of practicing or implementing the disclosure under the claims.

From the foregoing, it will be appreciated that specific embodiments have been described herein for purposes of illustration, but that various modifications may be made without deviating from the spirit and scope of the embodiments. Accordingly, the embodiments are not limited except as by the appended claims.

What is claimed is:

1. An electric vehicle system service equipment (EVSE) assembly, comprising:
a precast pad having:
a top layer; and
a bottom layer;
a charger mounted to the top layer of the precast pad; and
a power conversion cabinet mounted to the top layer of the precast pad.

2. The EVSE assembly of claim 1, wherein the bottom layer is a precast base layer that includes:
one or more ducts disposed on a top surface of the precast base layer and configured to receive a conduit from the charger and a conduit from the power conversion cabinet;
one or more cable troughs disposed within the precast base layer and configured to provide an exit point for cables running within the precast base layer; and
one or more channels disposed within the precast base layer and configured to couple the one or more cable troughs and contain the cables running through the precast base layer.

3. The EVSE assembly of claim 2, wherein the precast base layer includes one or more integrated bollard sleeves.

4. The EVSE assembly of claim 2, further comprising:
one or more connection troughs disposed proximate to at least one cable trough of the one or more cable troughs and configured to contain cables running from the precast base layer to a precast base layer of another EVSE assembly positioned adjacent to the EVSE assembly.

5. The EVSE assembly of claim 1, wherein the top layer comprises a precast metal frame upon which the charger and power conversion cabinet are mounted.

6. The EVSE assembly of claim 5, wherein the bottom layer includes a top surface having a geometry configured to receive the precast metal frame of the top layer.

7. The EVSE assembly of claim 5, wherein the precast metal frame includes:
a base frame;
one or more side frame components disposed on a side of the base frame; and
a metal plate disposed on top of the base frame and the one or more side frame components.

8. The EVSE assembly of claim 7, wherein the base frame supports the power conversion cabinet and the one or more side frame components support one or more chargers.

9. The EVSE assembly of claim 7, wherein the precast metal frame includes two side frame components disposed on each end of the base frame and configured to support a charger at each end of the EVSE assembly.

10. The EVSE assembly of claim 9, wherein the base frame includes one or more wireways that extend between the two side frame components within the base frame and contain cables or wires that extend between the power conversion cabinet and the chargers at each end of the EVSE assembly.

11. The EVSE assembly of claim 1, wherein the top layer is formed of aluminum and the bottom layer is formed of a concrete polymer.

12. The EVSE assembly of claim 1, wherein the top layer is partially disposed within the bottom layer.

13. The EVSE assembly of claim 1, wherein the bottom layer is partially disposed within the top layer.

14. An apparatus for mounting an electric vehicle system service equipment (EVSE) assembly, the apparatus comprising:
one or more ducts disposed on a top surface and configured to couple the apparatus to one or more EVSE components;
one or more cable troughs disposed within the apparatus and configured to provide an exit point for cables running within the apparatus; and
one or more channels disposed within the apparatus and configured to couple the one or more cable troughs and contain the cables running through the apparatus.

15. The apparatus of claim 14, further comprising:
a mounting area disposed within the top surface of the apparatus and configured to receive a mounting plate upon which the one or more EVSE components are mounted.

16. The apparatus of claim 14, further comprising:
one or more bollard sleeves integrated into a perimeter area of the apparatus.

17. The apparatus of claim 14, further comprising:
one or more connection troughs disposed proximate to at least one cable trough of the one or more cable troughs and configured to contain cables that extend out of the at least one cable trough to an external area of the apparatus.

18. A method of manufacturing an electric vehicle system service equipment (EVSE) assembly, the method comprising:
disposing a base ground interaction layer onto a site;
mounting an EVSE integration layer to the base ground interaction layer.

19. The method of claim 18, wherein the EVSE integration layer includes one or more chargers and a power conversion cabinet coupled to a mounting plate.

20. The method of claim 18, further comprising:
connecting the one or more chargers to the power conversion cabinet via cables that extend through conduit entrance ducts disposed on a top surface of the base ground interaction layer and within internal channels of the base ground interaction layer.
